(19) United States
(12) Patent Application Publication
(10) Pub. No.: US 2012/0188721 A1
(43) Pub. Date: Jul. 26, 2012

(54) NON-METAL STIFFENER RING FOR FCBGA

(75) Inventors: Chung Hsiung HO, Kaohsiung City (TW); Wen Hung HUANG, Kaohsiung City (TW); Pao Tung PAN, Kaohsiung City (TW); Ching Hui CHANG, Kaohsiung City (TW); I Pin CHEN, Kaohsiung City (TW)

(73) Assignee: NXP B.V., Eindhoven (NL)

(21) Appl. No.: 13/011,157

(22) Filed: Jan. 21, 2011

(51) Int. Cl. H05K 7/20

(52) U.S. Cl. 361/717

(57) ABSTRACT

PCB or similar material is used for stiffener rings supporting heat sinks in Flip Chip Ball Grid Array (FCBGA) packages. The substrate material of the package and the stiffener ring share the same or similar Coefficient of Thermal Expansion. Stiffener rings may be manufactured from PCB or similar material using a router.

### BACKGROUND

Ball grid array (BGA) is a type of integrated circuit packaging technology which is characterized by the use of a substrate whose upper surface is mounted with a semiconductor chip and whose lower surface is mounted with a grid array of solder balls. During a surface mount technology process, for example, the BGA package can be mechanically bonded and electrically coupled to a printed circuit board (PCB) by the grid array of solder balls.

Flip Chip Ball Grid Array (FCBGA) is a type of BGA technology that uses flip chip technology in mounting the active side of the chip die in an upside-down manner over the substrate and bonded to the substrate by the use of solder bumps attached to the input/output pads of the die. Due to coefficient of thermal expansion mismatches between the die and the FCBGA package components, such as for example, the substrate and underfill (an adhesive flowed between the chip and substrate) and thermal stresses are frequently induced in the FCBGA package. Thermal issues for the die may be reduced by attaching a heat sink to the die where the heat sink is mechanically supported by a stiffener ring.

### BRIEF DESCRIPTION OF THE DRAWINGS

FIG. 1a shows a prior art FCBGA package with heat sink in side view.

FIG. 1b shows a prior art FCBGA package in top view.

FIG. 1c shows a prior art FCBGA package with heat sink in side view.

FIG. 1d shoe s a prior art FCBGA package with heat sink in side view.

FIG. 2 shows FCBGA package with heat sink in side view in an embodiment in accordance with the invention.

FIG. 3 shows an FCBGA package in top view in an embodiment in accordance with the invention.

FIG. 4a shows the PCB layout for “O” shaped stiffener rings in an embodiment in accordance with the invention.

FIG. 4b shows the PCB layout for “C” shaped stiffener rings in an embodiment in accordance with the invention.

FIG. 5 shows multilayer stacking of PCB layout for “C” shaped stiffener rings in an embodiment in accordance with the invention.

### DETAILED DESCRIPTION

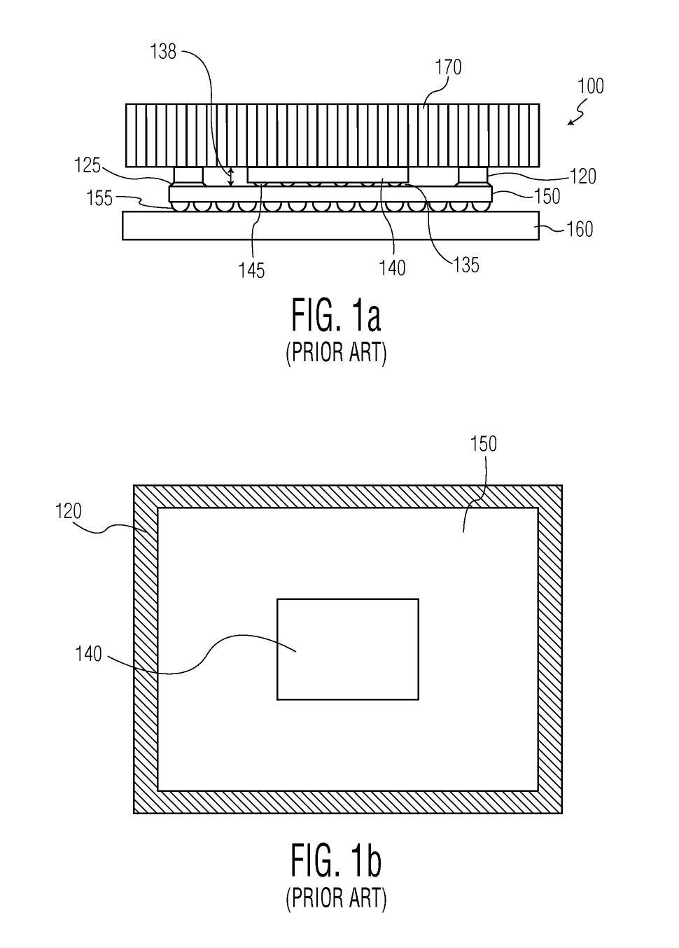

FIG. 1a shows a cross-sectional view of a typical prior art flip chip ball grid array package (FCBGA) 100. FCBGA package 100 includes die 140 which is attached to contact pads (not shown) on underlying substrate 150 using solder bumps 145. Underfill 135 is typically used between die 140 and substrate 150 to provide adhesion to help protect die 140 from separating from substrate 150 of FCBGA package 100. Solder balls 155 are typically attached to contact pads (not shown) on the bottom of substrate 150 to typically provide electrical contact with and attachment of FCBGA package 100 to printed circuit board (PCB) 160 or other substrates such as a ceramic type material. Aluminum or other typical metal “O” type stiffener ring 120 is mounted on substrate 150 using adhesive 125 and heat sink 170 is mounted on top of die 140 of FCBGA package 100. FIG. 1b shows a top view of prior art FCBGA package 100 with heat sink 170 removed to show typical metal “O” type stiffener ring 120. Heat sink 170 is used to dissipate heat generated by die 140 and stiffener ring 120 functions to support gap 138 created by die 140 and solder bumps 145 so that good contact can be maintained between die 140 and heat sink 170. Typical prior art FCBGA packages 100 may have a thermal interface material (not shown) inserted between die 140 and heat sink 170 to help transfer heat from die 140 to heat sink 170. Metal stiffener rings 120 typically are available only in specific thicknesses, so the size of gap 138 may not be closely matched by the thickness of metal stiffener ring 120. This can lead to less than optimal thermal contact between die 140 and heat sink 170 by creating gap 101 if the thickness of metal stiffener ring 120 is too thick as shown in FIG. 1c in cross-section. If the thickness of metal stiffener ring 120 is too thin as shown in FIG. 1d in cross-section this can lead to less than optimal thermal contact between die 140 and heat sink 170 by causing heat sink 170 to tilt thereby creating gap 102. Both gap 101 and gap 102 adversely effect the ability of heat sink 170 to dissipate heat from die 140.

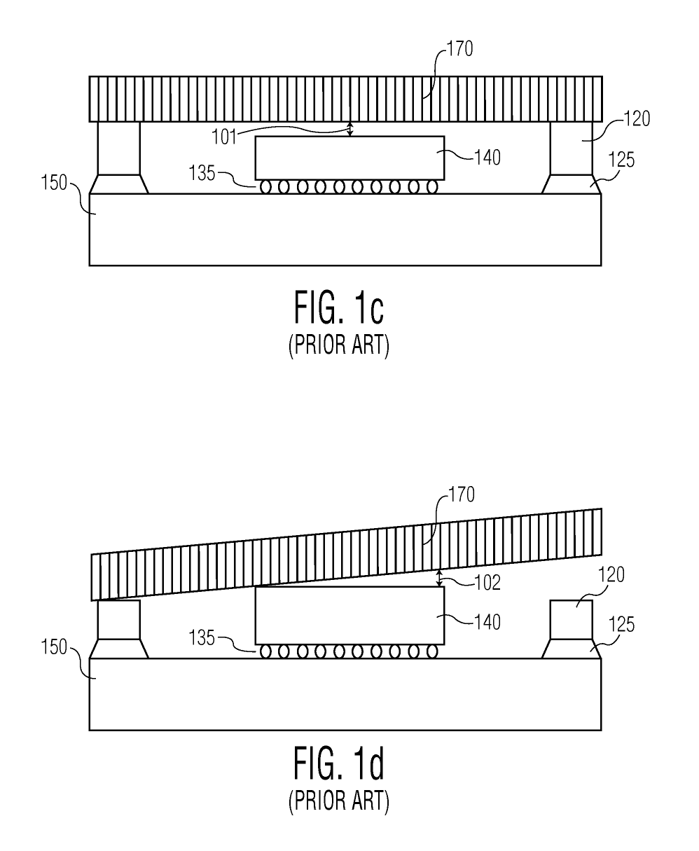

FIG. 2 shows a cross-sectional view of an embodiment in accordance with the invention. FCBGA package 200 includes die 240 which is attached to contact pads (not shown) on underlying substrate 250 using solder bumps 245. Underfill 235 is typically used between die 240 and substrate 250 to provide adhesion to help protect die 240 from separating from substrate 250 of FCBGA package 200. Solder balls 255 are typically attached to contact pads (not shown) on the bottom of substrate 250 to typically provide electrical contact with and attachment of FCBGA package 200 to printed circuit board (PCB) 160 or other substrates. Stiffener ring 220 is mounted on substrate 250 using adhesive 225 and heat sink 270 is mounted on top of die 240 of FCBGA package 200. In accordance with the invention, stiffener ring 220 is made from the same material, for example, PCB, as substrate 250 to obtain the same CTE for both stiffener ring 220 and substrate 250 to reduce CTE mismatch effects. In the prior art stiffener ring 120 is typically made from aluminum or other metal that does not have the same CTE as substrate 250 but may match or be close to the CTE of heat sink 270. Heat sink 270 is used to dissipate heat generated by die 240. Stiffener ring 220 functions to provide support to heat sink 270 ensuring that heat sink 270 is in good thermal contact with die 240.

The use of PCB or similar material for stiffener ring 220 affords a cost savings because using PCB or similar material is typically cheaper than using metal such as aluminum. Using PCB or similar material for stiffener ring also allows a better thickness match by stiffener ring 220 to gap 238 formed by the combined thickness of solder bumps 245 and die 240. This is because it is relatively easy to customize the thickness of PCB or similar material. The thickness of PCB or similar material can typically be adjusted by varying the thickness of the dielectric layers that are laminated together, by varying the number of dielectric layers that are laminated together, changing the thickness of the epoxy resin prepreg (PP) layer that laminates the dielectric layers together or by varying the solder mask thickness. Hence, there are numerous ways to adjust the thickness of a PCB material thereby allowing for a precise control of the thickness of stiffener ring 220 and avoiding the formation of gaps 101 and 102 as shown in FIGS. 1c and 1d, respectively.

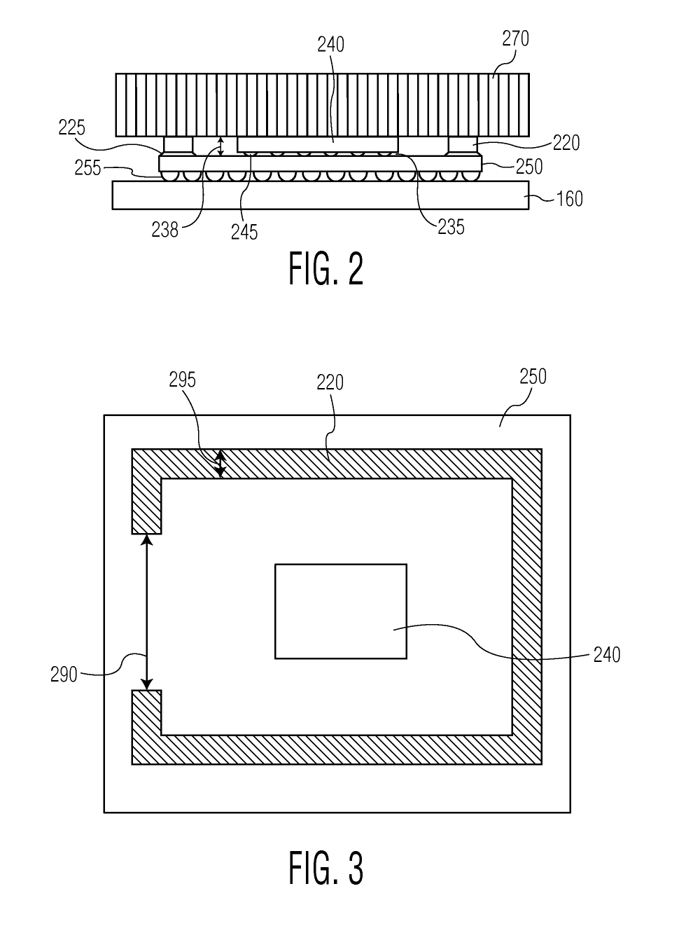

FIG. 3 shows a top view of FCBGA package 200 with heat sink 270 removed to show stiffener ring 220 having a “C” type shape in an embodiment in accordance with the invention instead of the typical “O” shape used in the prior art. Typically, gap 290 of stiffener ring 220 is greater than twice thickness 295 of stiffener ring 220.

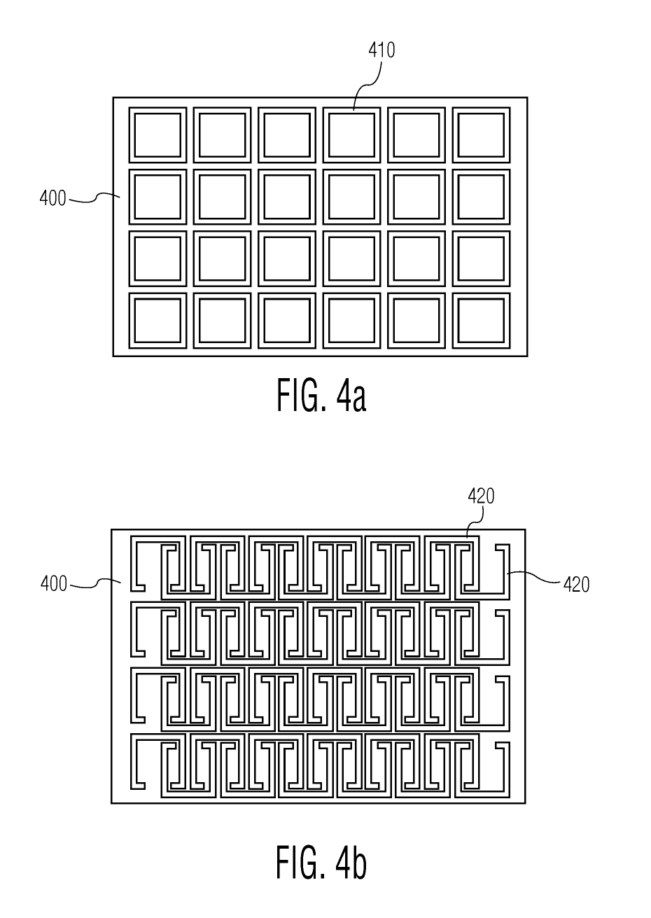

Use of the “C” shape for stiffener ring 220 in accordance with the invention instead of the typical “O” shape, allows for material cost savings while not adversely effecting the performance of stiffener ring 220 in supporting heat sink 270. The ability of a “C” shape for stiffener ring 220 to save material costs is shown in FIGS. 4a and 4b. For a given size substrate panel 400, typically made from PCB material in an embodiment in accordance with the invention, FIG. 4a shows the layout design for making typical “O” type stiffener rings 410. Note that substrate panel 400 is made from the same material as substrate 250 to ensure that the CTE is substantially the same in accordance with the invention. In this exemplary embodiment, 24 “O” type stiffener rings 410 may be obtained from substrate panel 400 but the area inside “O” type stiffener ring 410 is wasted on the production of stiffener ring 410. In contrast, FIG. 4b shows the layout design for making “C” type stiffener rings 420 in an embodiment in accordance with the invention. FIG. 4b shows that 48 “C” type stiffener rings 420 may be obtained from substrate panel 400 by making a “C” type stiffener ring in contrast to an “O” type stiffener ring. Hence, the yield from substrate panel 400 is doubled by using “C” type stiffener ring 420 in an embodiment in accordance with the invention. Both “O” type stiffener ring 410 and “C” type stiffener ring 420 may be manufactured from substrate panel 400 by using a router typically used in substrate factories to cut substrates such as PCB. Routers in substrate factories are milling cutters that are typically computer controlled and able to cut out shapes such as stiffener rings 410 and 420 shown in FIGS. 4a and 4b.

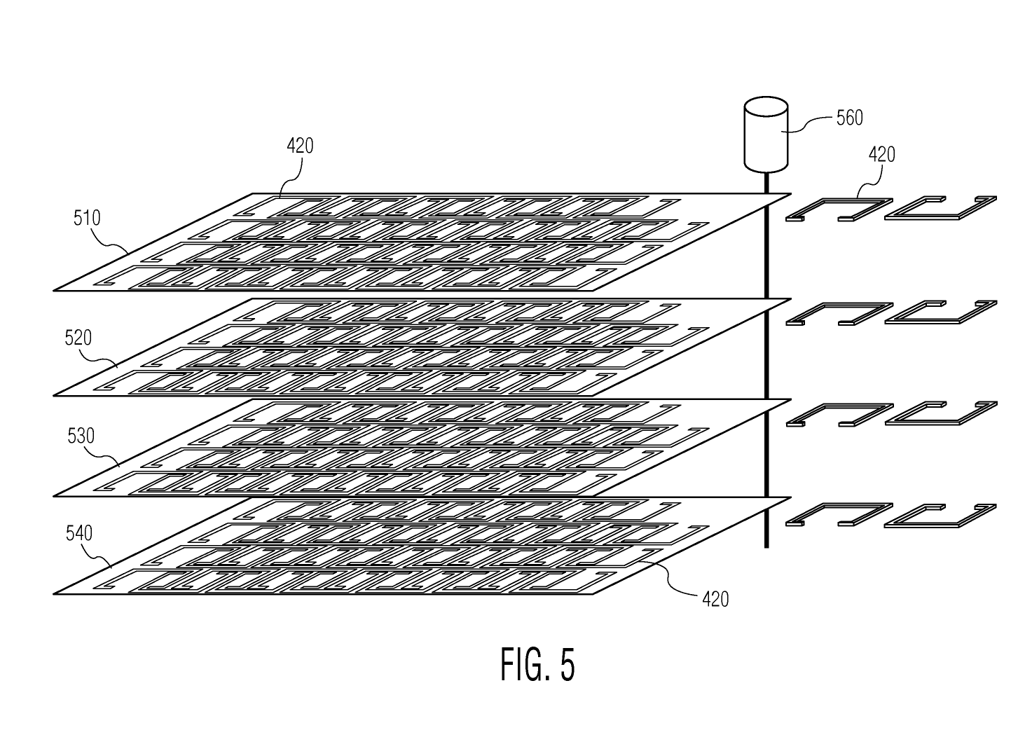

In order to increase the capacity for manufacturing stiffener rings 410 and 420 by router 560, substrate panels 400 may be typically stacked in four or more layers in accordance with the invention as shown in FIG. 5. In FIG. 5, substrate panels 510, 520, 530 and 540 are vertically stacked such that as router 560 cuts out stiffener ring 420 in substrate panel 510, stiffener rings 420 are also cut out in substrate panels 520, 530 and 530 thereby increasing production capacity for stiffener rings 420. Depending on the total thickness of substrate panels 510, 520, 530 and 540 and the capabilities of router 560 more than four substrate panels 510, 520, 530 and 540 may be vertically stacked to increase production capacity in accordance with the invention.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

1. An assembly comprising:
a substrate;
a semiconductor die mounted on the first side of the substrate;
a ring structure having a first thickness comparable to the die and a shape, the ring structure being bonded to a first side of the substrate; and
a heat sink attached to the ring structure such that the ring structure provides mechanical support for the heat sink and where the ring structure is made from substantially the same material as the substrate.

2. The assembly of claim 1 wherein the substrate is made from printed circuit board (PCB) material.

3. The assembly of claim 2 wherein the ring structure is comprised of a number of dielectric layers, each layer having a thickness, laminated together using an epoxy resin prepreg.

4. The assembly of claim 3 wherein the ring structure is further comprised of a solder mask layer.

5. The assembly of claim 3 wherein the first thickness of the ring structure is adjusted by varying the number of dielectric layers.

6. The assembly of claim 3 wherein the first thickness of the ring structure is adjusted by varying the thickness of at least one of the number of dielectric layers.

7. The assembly of claim 4 wherein the first thickness of the ring structure is adjusted by varying the thickness of the solder mask layer.

8. The assembly of claim 1 where the ring structure has the shape of a “C”.

9. The assembly of claim 8 where the ring structure is created by cutting the ring structure shape out of a PCB panel using a computer controlled router.

10. The assembly of claim 8 wherein a plurality of ring structures are created by cutting the ring structure shape out of a plurality of PCB panels stacked on top of one another by using a computer controlled router.
